(19) United States
(12) Patent Application Publication
(10) Pub. No.: US 2025/0182998 A1
(43) Pub. Date: Jun. 5, 2025

(54) SIGNAL ELECTRON BEAM DEFLECTOR FOR AN ELECTRON BEAM APPARATUS, ELECTRON BEAM APPARATUS AND METHOD OF DEFLECTING A SIGNAL ELECTRON BEAM

(71) Applicant: ICT Integrated Circuit Testing Gesellschaft für Halbleiterprüftechnik mbH, Heimstetten (DE)

(72) Inventors: Pieter Kruit, Delft (NL); Stanislav Bardy, München (DE)

(73) Assignee: ICT Integrated Circuit Testing Gesellschaft für Halbleiterprüftechnik mbH, Heimstetten (DE)

(21) Appl. No.: 18/526,553

(22) Filed: Dec. 1, 2023

(51) Int. Cl. H01J 37/147; H01J 37/05

(52) U.S. Cl. CPC H01J 37/1472; H01J 37/05

(57) ABSTRACT

A signal electron beam deflector for an electron beam apparatus is provided. The signal electron beam deflector includes a first electrode extending in a curved manner; and a second electrode extending in a curved manner and having at least one electron transparent portion configured for a signal electron beam to pass through the at least one electron transparent portion. The first electrode and the second electrode are arranged adjacent to each other to form a space between the first electrode and the second electrode. The space has an entrance opening and an exit opening; a first optical path is provided between the entrance opening and the exit opening; and a second optical path is provided between the entrance opening and the at least one electron transparent portion of the second electrode.

### TECHNICAL FIELD

Embodiments of the present disclosure relate to electron beam apparatuses, for example, for inspection system applications, testing system applications, lithography system applications, defect review, critical dimensioning applications or the like. In particular, embodiments of the present disclosure relate to signal electron beam deflectors for an electron beam apparatus. Embodiments of the present disclosure specifically relate to a signal electron beam deflector for an electron beam apparatus, an electron beam apparatus, and a method of deflecting a signal electron beam.

### BACKGROUND

Modern semiconductor technology has created a high demand for structuring and probing samples in the nanometer or even in the sub-nanometer scale. Micrometer and nanometer-scale process control, inspection or structuring, is often done with electron beams, which are generated, shaped, deflected and focused in electron beam apparatuses, such as electron microscopes or electron beam pattern generators. For inspection purposes, charged electron beams offer a superior spatial resolution compared to, for example, photon beams.

Apparatuses using electron beams, such as scanning electron microscopes (SEM), have many functions in a plurality of industrial fields, including, but not limited to, inspection of electronic circuits, exposure systems for lithography, detecting systems, defect inspection tools, and testing systems for integrated circuits. In such electron beam systems, fine beam probes with a high current density can be used. For instance, in the case of an SEM, the primary electron beam generates signal electrons like secondary electrons (SEs) and/or backscattered electrons (BSEs) when impinging on a sample that can be used to image and/or inspect the sample.

In a scanning electron microscope (SEM), the BSEs from the sample are beneficially detected with high efficiency. Selection of the emission angle and energy of the BSEs may contain information of the sample. There is a tendency to use higher acceleration energies in SEM, even going up to 100 keV which means BSEs also have high energies. At the same time, it is beneficial to detect the SEs. Sometimes, it is beneficial to distinguish between the azimuthal angle of emission, e.g. in order to get topography contrast.

Electron beam apparatuses can have different detection optics. Some electron beam apparatuses are provided with a segmented detector, e.g. quadrant SEs detector. For example, an in-lens detector (ILD) on an optical axis, e.g. between an objective lens and a beam separator can be provided. Some electron beam apparatuses deflect signal electrons by larger angles, e.g. 60° or more onto a secondary optical axis, where the energy can be filtered.

In view of the above, improved apparatuses and methods that enable simultaneously measuring of fast BSEs, e.g. generated at higher acceleration energies, for example up to 100 keV, and SEs, would be beneficial. Embodiments of the present disclosure aim at providing signal electron beam deflectors for an electron beam apparatus, electron beam apparatuses, and methods for deflecting a signal electron beam.

### SUMMARY

In light of the above, signal electron beam deflectors for an electron beam apparatus, electron beam apparatuses, and methods of deflecting a signal electron beam are provided. Further aspects, benefits, and features of the present disclosure are apparent from the claims, the description, and the accompanying drawings.

According to an aspect, a signal electron beam deflector for an electron beam apparatus is provided. The signal electron beam deflector includes a first electrode extending in a curved manner, and a second electrode extending in a curved manner and having at least one electron transparent portion. The first electrode and the second electrode are arranged adjacent to each other to form a space between the first electrode and the second electrode, such that: the space has an entrance opening and an exit opening, a first optical path is provided between the entrance opening and the exit opening, and a second optical path is provided between the entrance opening and the at least one electron transparent portion of the second electrode.

According to an aspect, a signal electron beam deflector for an electron beam apparatus is provided. The signal electron beam deflector includes a first electrode and a second electrode providing a first optical path therebetween, and at least one electron transparent portion provided in the second electrode. A second optical path is provided, the second optical path passing through the at least one electron transparent portion, and the signal electron beam deflector is configured to guide electrons of a signal electron beam along the first optical path and along the second optical path according to an energy of the electrons of the signal electron beam.

According to an aspect an electron beam apparatus is provided. The electron beam apparatus includes a sample stage, a deflector system, an electron source adapted to generate a primary electron beam and a signal electron beam deflector according to embodiments described herein.

According to an aspect, a method of deflecting a signal electron beam is provided. The method includes guiding a signal electron beam from a sample to a signal electron beam deflector, the signal electron beam deflector having a first electrode and a second electrode: guiding slow electrons of the signal electron beam along a first optical path, the first optical path being provided between an entrance opening and an exit opening of the signal electron beam deflector; and guiding fast electrons of the signal electron beam along a second optical path, the second optical path being provided between the entrance opening and a at least one electron transparent portion provided in the second electrode of the signal electron beam deflector. Further advantages, features, aspects and details that can be combined with embodiments described herein are evident from the dependent claims, the description and the drawings.

### BRIEF DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic view of a signal electron beam deflector according to embodiments described herein:

FIG. 2A shows a schematic view of a signal electron beam deflector wherein the second electrode is provided as an electron transparent grid according to embodiments described herein:

FIG. 2B shows a schematic view of a signal electron beam deflector wherein the second electrode is provided as an electron transparent foil according to embodiments described herein:

FIGS. 3A-3C are schematic cross-sectional views of the first electrode and the second electrode of a signal electron beam deflector according to embodiments described herein:

FIG. 4 shows a schematic view of an electron beam apparatus having a signal electron beam deflector according to embodiments described herein:

FIG. 5 shows a flow chart of a method of deflecting a signal electron beam according to embodiments described herein.

### DETAILED DESCRIPTION

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

In an electron beam apparatus, a signal electron beam may be emitted from a sample by impinging a primary electron beam on the sample. The signal electron beam may be detected to obtain information about the sample, e.g. imaging of the sample. Signal electron beam deflectors may deflect a signal electron beam. For example, signal electron beam deflectors may deflect the signal electron beam to guide the signal electron beam to a detector. The signal electron beam deflectors may include electrodes, e.g. a first electrode and a second electrode, configured to deflect the signal electron beam. The signal electron beam may be guided along an optical path towards a detector, e.g. guided along a first optical path provided in a space between the first electrode and the second electrode.

The resolution and/or throughput of an electron beam apparatus, may be improved by detecting all or most electrons. A signal electron beam can be guided through the signal electron beam deflector to a detector, e.g. along the first optical path. Some electrons, e.g. fast BSEs, of the signal electron beam may have an energy that is too high to be deflected along the first optical path. The signal electron beam deflector of the present disclosure is provided with a at least one electron transparent portion in the second electrode. The at least one electron transparent portion provided in the second electrode provides a second optical path. The fast BSEs can be deflected along the second optical path. Advantageously, the fast BSEs can exit the signal electron beam deflector through the at least one electron transparent portion and can be guided to a detector. In some embodiments, the at least one electron transparent portion includes a beam opening provided in the second electrode. The beam opening may be a slit provided in the second electrode. An electron transparent grid or an electrons transparent foil may be provided at least partially overlapping the beam opening.

In some embodiments, the at last one electron transparent portion includes an electron transparent grid or an electron transparent foil. The grid or foil is highly transparent to signal electrons, particularly BSEs, and lets signal electrons pass through the grid or foil while a potential distribution in the signal electron beam deflector is substantially not disturbed. The at least one electron transparent portion, including, for example, an electron transparent grid or foil, may let BSEs pass to detectors above. Beneficially, signal electron beam deflectors of the present application provide for higher detection efficiency of fast BSEs. The higher detection efficiency of fast BSEs increases the throughput of electron beam apparatuses of the present disclosure and/or electron beam apparatuses having the signal electron beam deflector according to embodiments described herein. Advantageously, the signal electron beam deflector allows to detect BSEs and SEs simultaneously. Combination of BSEs and SEs detection provides better contrast for features detected with an electron beam apparatus.

Backscattered electrons and secondary electrons may be deflected away from the optical path of the primary electrons, e.g. deflected to be guided to a detector. Signal electron beam deflectors may be limited to certain energy bands of electrons that can be deflected at the same time. The signal electron beam deflector according to the present disclosure allows to detect both the fast BSEs, having an energy of up to 20 keV, even up to 100 keV, (upon being released from the sample) and the slow BSEs and SEs, having an energy down to a few eV (upon being released from the sample), at the same time, by creating an exit path for the fast BSEs. The signal electron beam deflector according to the present disclosure allows to simultaneously detect BSEs, e.g. for depth information, and SEs, e.g. for surface information, particularly both with high collection efficiency. For fast BSEs detection and also SEs detection, an electron beam apparatus may have an in-lens SEs detector that is placed with an opening for the fast BSEs. This limits the BSEs signal and thus a throughput of an electron beam apparatus. The signal electron beam deflector according to the present disclosure allows to remove the in-lens SEs detector. The BSEs signal and the throughput can be increased.

Throughout this application and if not otherwise indicated, electrons are referred to, depending on their energy, as follows. Electrons having, upon emission of the signal electron beam from the sample, an energy of less than 100 eV or less than 1 keV are referred to as slow electrons; and electrons having, upon emission of the signal electron beam from the sample, an energy of more than 1 keV are referred to as fast electrons. Further, in some embodiments an acceleration energy may be provided to the signal electron beam. The fast electrons and the slow electrons can be accelerated by a voltage that increases the energy of the slow electrons and the fast electrons by a value corresponding to this voltage, i.e. the same voltage. The acceleration energy may be corresponding to an acceleration voltage Vₐ. The acceleration voltage may be up to 10 kV, particularly up to 30 kV or even more. The acceleration energy may be up to 10 keV, particularly up to 30 keV or even more. Electrons to which the acceleration energy is provided and which have an energy of less than an acceleration energy +100 eV or less than acceleration energy +1 keV are referred to as slow electrons within the deflector; and electrons to which the acceleration energy is provided and which have an energy of more than an acceleration energy +1 keV are referred to as fast electrons within the deflector.

### Signal Electron Beam Deflector

According to an aspect, a signal electron beam deflector for an electron beam apparatus is provided. The signal electron beam deflector includes a first electrode extending in a curved manner, and a second electrode extending in a curved manner and having at least one electron transparent portion configured for having a portion of a signal electron beam to pass through the at least one electron transparent portion. The first electrode and the second electrode are arranged adjacent to each other to form a space between the first electrode and the second electrode, such that: the space has an entrance opening and an exit opening, a first optical path is provided between the entrance opening and the exit opening, and a second optical path is provided between the entrance opening and the at least one electron transparent portion of the second electrode. The at least one electron transparent portion may be configured for electrons to pass through the at least one electron transparent portion.

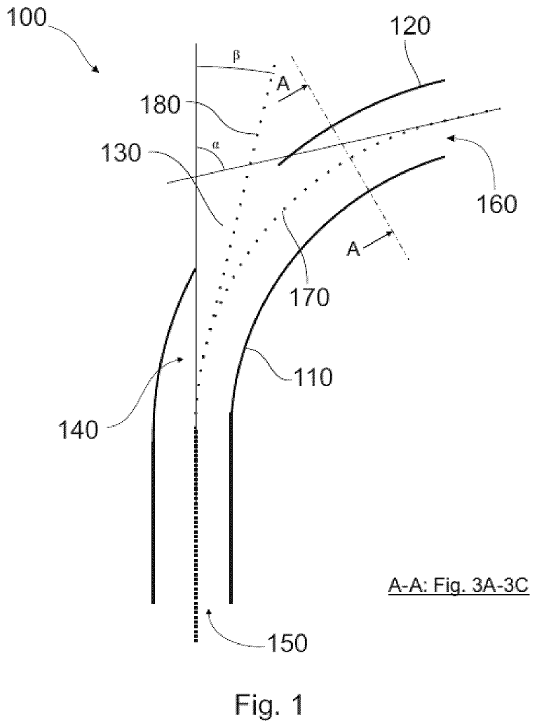

FIG. 1 is a schematic illustration of a signal electron beam deflector 100 according to embodiments disclosed herein. The signal electron beam deflector 100 includes a first electrode 110 extending in a curved manner and a second electrode 120 extending in a curved manner. The second electrode 120 has at least one electron transparent portion 130. The at least one electron transparent portion may be configured for a portion of the signal electron beam to pass through the at least one electron transparent portion. The at least one electron transparent portion 130 is provided in the second electrode 120. In the embodiment of FIG. 1, the at least one electron transparent portion includes a beam opening provided in the second electrode 120. The first electrode 110 and the second electrode 120 are arranged adjacent to each other to form a space 140 between the first electrode and the second electrode. The space 140 has an entrance opening 150 and an exit opening 160. A first optical path 170 is provided between the entrance opening 150 and the exit opening 160. A second optical path 180 is provided between the entrance opening 150 and the at least one electron transparent portion 130.

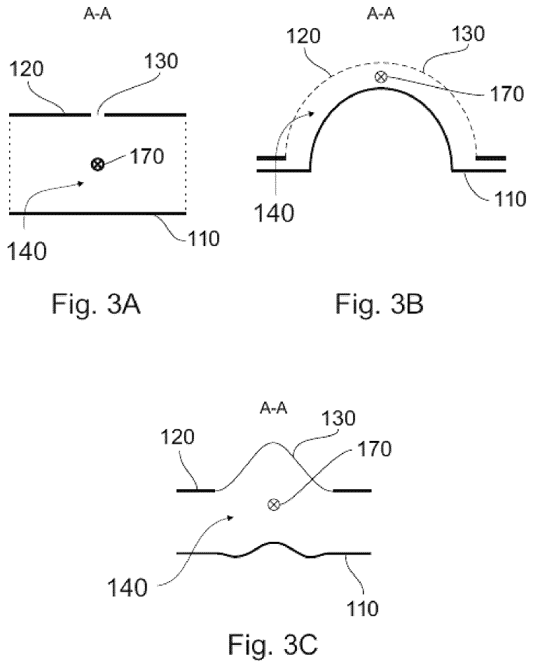

The first electrode 110 is extending in a curved manner. The first electrode 110 may extend in an elliptical manner, particularly a circular manner. The first electrode 110 may extend in an exponential manner. Particularly, the first electrode may extend along a first path that is defined by an elliptical arc, particularly a circular arc, or extend along a first path that is defined by an exponential function or a polynomial function. The first electrode 110 may extend in a direction perpendicular to the first path, i.e. have a cross section as shown, for example, in FIGS. 3A-3C. The first path may be in a same plane as the first optical path 170. The first path and the first optical path 170 path may be parallel curves.

The second electrode 120 is extending in a curved manner. The second electrode 120 may extend in an elliptical manner, particularly a circular manner. The second electrode 120 may extend in an exponential manner. Particularly, the second electrode 120 may extend along a second path that is defined by an elliptical arc, particularly a circular arc, or extend along a second path that is defined by an exponential function or a polynomial function. The second electrode 120 may extend in a direction perpendicular to the second path, i.e. have a cross section as shown, for example, in FIGS. 3A-3C. The second path may be in a same plane as the first optical path 170. Particularly, the first path, the second path, and the first optical path 170 may be in a same plane. The second path and the first optical path 170 may be parallel curves. Particularly, the first path, the second path, and the first optical path 170 may be parallel curves. The first electrode 110 and the second electrode 120 may be arranged parallel to each other.

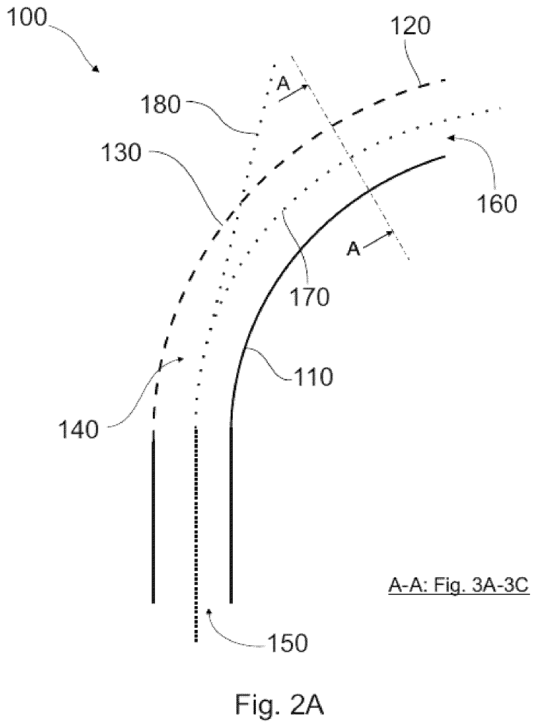

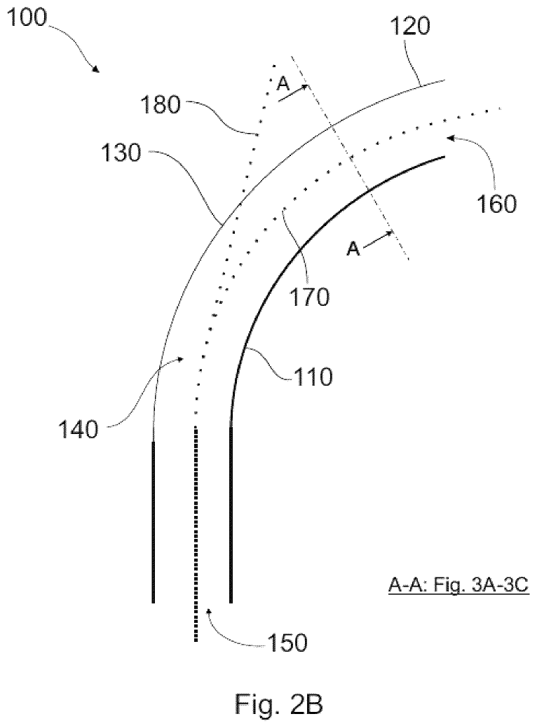

The second electrode may be provided as an electron transparent grid. FIG. 2A shows an embodiment, in which the second electrode is provided as an electron transparent grid. The at least one electron transparent portion 130 may extend substantially over the entire surface of the second electrode 120 that is provided as an electron transparent grid. The second electrode may be provided as an electron transparent foil. FIG. 2B shows an embodiment, in which the second electrode is provided as an electron transparent grid. The at least one electron transparent portion 130 may extend substantially over the entire surface of the second electrode 120 that is provided as an electron transparent grid. Advantageously, providing the second electrode as an electron transparent grid or an electron transparent foil allows to guide electrons from the entrance opening 150 through substantially any location on the surface of the second electrode that is provided as an electron transparent grid or an electron transparent membrane. The throughput of fast electrons along the second optical path is increased and losses of fast electrons in the signal electron beam deflector can be reduced. In an embodiment, which can be combined with other embodiments described herein, the second electrode is provided as an electron transparent grid or an electron transparent foil such that the at least one electron transparent portion extends substantially over the entire surface of the second electrode that is provided as an electron transparent grid or an electron transparent foil.

In some embodiments, the first electrode is extending in an elliptical manner and the second electrode is extending in an elliptical manner. Particularly, the first electrode is extending in a circular manner and the second electrode is extending in a circular manner. The first electrode extending in a circular manner and the second electrode extending in a circular manner may be arranged concentric.

The space 140 is formed, at least partially, between the first electrode 110 and the second electrode 120. The first electrode 110 and the second electrode 120 may be arranged to define the space 140 therebetween. The first electrode 110 and the second electrode 120 may define the space 140 without being in direct contact. The first electrode 110 and the second electrode 120 may form the space 140 as a volume which is formed between the electrodes and a virtual line (see dotted line in FIG. 3A) between the edges of the first electrode 110 and the second electrode 120, particularly, a straight line between the edges of the first electrode 110 and the second electrode 120.

The space 140 has the entrance opening 150 and the exit opening 160. The entrance opening 150 may be configured for a signal electron beam to pass through the entrance opening 150. The exit opening 160 may be configured for a portion of the signal electron beam to pass through the exit opening 160. The exit opening 160 may be configured for a signal electron beam to pass through the exit opening 160. A signal electron beam may enter the space 140 through the entrance opening 150. The signal electron beam may exit the space 140 through the exit opening 160. The signal electron beam may propagate inside the space 140. The signal electron may propagate along the first optical path 170. The signal electron beam may propagate along the second optical path 180.

The first optical path 170 is provided between the entrance opening 150 and the exit opening 160. The first optical path may extend from the entrance opening 150 to the exit opening 160. The first optical path may be provided within the space 140. The first optical path 170 may be provided between the first electrode 110 and the second electrode 120. A signal electron beam may be guided along the first optical path. The signal electron beam may enter the space 140 through the entrance opening 150. The signal electron beam may exit the space through the exit opening 160.

A second optical path 180 is provided between the entrance opening 150 and the at least one electron transparent portion 130. The second optical path 180 may extend from the entrance opening to the at least one electron transparent portion 130. A signal electron beam propagating in the space 140 between the first electrode 110 and the second electrode 120 may pass through the at least one electron transparent portion 130 and pass through the second electrode. The signal electron beam may be guided along the second optical path. The signal electron beam may enter the space 140 through the entrance opening 150 and exit the space 140 through the at least one electron transparent portion 130.

The at least one electron transparent portion 130 may include a beam opening provided in the second electrode 120. The beam opening may be configured for a portion of the signal electron beam to pass through the beam opening. The beam opening may be configured for a signal electron beam to pass through the beam opening. The beam opening may include one or more openings provided in the second electrode 120. Particularly, the one or more openings provided in the second electrode 120 may be through holes. The one or more openings may be provided in the electrode. The one more openings provided as through holes in the second electrode 120 may extend through the second electrode 120. The one or more openings may be configured for a portion of the signal electron beam to pass through the one or more openings. The second optical path 180 may be provided between the entrance opening 150 and at least one of the one or more openings included in the beam opening. The second optical path 180 may extend from the entrance opening 150 to at least one of the one or more openings included in the beam opening. A signal electron beam may exit the space 140 through the beam opening. Particularly, the signal electron beam may exit the space 140 through at least one of the one or more openings of the beam opening.

The beam opening may be a slit in the second electrode 120. The slit may extend partially or fully between a first end of the second electrode and a second end of the first electrode. The first end of the second electrode may be adjacent to the entrance opening. The second end of the second electrode may be adjacent to the exit opening. The slit may be arranged anywhere between the first end of the second electrode and the second end of the second electrode. The second optical path 180 may extend from the entrance opening 150 to the slit in the second electrode 120 provided as the beam opening. A signal electron beam may exit the space 140 through the slit in the second electrode 120 provided as the beam opening. In one embodiment, the at least one electron transparent portion 130 includes a beam opening in the second electrode. Particularly, the beam opening being a slit in the second electrode extending between a first end of the second electrode at the entrance opening and a second end of the second electrode at the exit opening.

An electron transparent grid or an electron transparent foil may be provided, partially overlapping the beam opening. The electron transparent grid or electron transparent foil may be fully overlapping the beam opening.

In an embodiment a signal electron beam deflector for an electron beam apparatus is provided. The signal electron beam deflector including: a first electrode 110 extending in a curved manner: a second electrode 120 extending in a curved manner and having at least one electron transparent portion; and a beam opening provided in the second electrode 120. The first electrode 110 and the second electrode 120 are arranged adjacent to each other to form a space 140 between the first electrode and the second electrode, such that: the space 140 has an entrance opening 150 and an exit opening 160: a first optical path 170 is provided between the entrance opening 150 and the exit opening 160; and a second optical path 180 is provided between the entrance opening 150 and the beam opening provided in the second electrode.

The first optical path 170 may be curved over a first angle α, as shown in FIG. 1. The first electrode extending in the curved manner may be curved over the first angle α. The second electrode extending in the curved manner may be curved over the first angle α. The first angle α is defined between a direction of the first optical path 170 at the position of the entrance opening 150 and the direction of the first optical path 170 at the position of the exit opening 160. The first angle α may be between 30° and 90°.

A signal electron beam propagating along the first optical path 170 through the signal electron beam deflector 100 may enter the signal electron beam deflector through the entrance opening 150 having a first propagation direction. The signal electron beam may exit the signal electron beam deflector through the exit opening 160 having a second propagation direction. The second propagation direction may have the first angle α to the first propagation direction. Particularly, a signal electron beam may enter the signal electron beam deflector 100 through the entrance opening 150 having a first propagation direction. A slow signal electron beam may exit the signal electron beam deflector 100 through the exit opening having a second propagation direction. The second propagation direction of the slow signal electron beam may have the first angle α to the first propagation direction of the signal electron beam. The signal electron beam deflector 100 may deflect electrons which are guided along the first optical path by the first angle α. The signal electron beam deflector 100 may deflect slow electrons by the first angle α.)

The second optical path 180 may be curved over a second angle β, as shown in FIG. 1. The at least one electron transparent portion may be provided in the second electrode such that the second optical path may be curved over the second angle β. The second angle β being measured between a direction of the second optical path 180 at the position of the entrance opening 150 and the direction of the second optical path at the position of the at least one electron transparent portion 130. The second angle β may be between substantially 10° and 80°. The second angle β may be less than the first angle α. In one embodiment, the first angle α is between 80° and 90° and the second angle β is between 30° and 80°.

A signal electron beam propagating along the second optical path 180 through the signal electron beam deflector 100 may enter the signal electron beam deflector through the entrance opening 150 with a first propagation direction. The signal electron beam may exit the signal electron beam deflector through the at least one electron transparent portion 130 having a second propagation direction. The second propagation direction may have the second angle β to the first propagation direction. Particularly, the signal electron beam may enter the signal electron beam deflector 100 through the entrance opening 150 having a first propagation direction. A fast signal electron beam may exit the signal electron beam deflector 100 through the at least one electron transparent portion 130 having a second propagation direction. The second propagation direction of the fast signal electron beam may have the second angle β to the first propagation direction of the signal electron beam. The signal electron beam deflector 100 may deflect electrons which are guided along the second optical path by the second angle β. The signal electron beam deflector may deflect fast electrons by the second angle β.

The first electrode 110 may be made of a conductive material. The first electrode may be configured to apply a first voltage to the first electrode. The first electrode 110 may be configured to provide a first electrical field. The first voltage may be applied to the first electrode 110 to provide a first electrical field by the first electrode.

The second electrode 120 may be made of a conductive material. The second electrode may be configured to apply a second voltage to the second electrode. The second electrode 120 may be configured to provide a second electrical field. The second voltage may be applied to the second electrode 120 to provide a second electrical field by the second electrode.

The first electrical field and/or the second electrical field may be used to deflect a signal electron beam propagating through the signal electron beam deflector. The first electrical field and/or the second electrical field may deflect slow electrons of the signal electron beam along the first optical path. The first electrical field and/or the second electrical field may deflect fast electrons of the signal electron beam along the second optical path. Disturbances within the first electrical field and/or the second electrical field may disturb the deflecting of the slow electrons and/or the fast electrons.

The at least one electron transparent portion may include an electron transparent grid. The electron transparent grid may be formed integrally with the second electrode. The electron transparent grid may be configured for a portion of a signal electron beam to pass through the electron transparent grid.

The electron transparent grid may include a plurality of overlapping wires or nano-structures forming a mesh. The plurality of overlapping wires or nano-structures may form a plurality of openings between the plurality of overlapping wires or nano-structures. An electron beam may pass through the plurality of openings between the plurality of overlapping wires or nano-structures. The electron transparent grid may be highly transparent to electrons. The grid may have an electron transparency of more than 50%, particularly more than 70%. The grid may be implemented in a micro-electromechanical system (MEMS).

The electron transparent grid may be configured to apply a voltage to the electron transparent grid. The electron transparent grid may be electrically connected to the second electrode 120. The electron transparent grid may be configured to apply a same voltage which is applied to the second electrode 120 to the electron transparent grid. Particularly, the electron transparent grid may be configured to apply the second voltage applied to the electron transparent grid. The electron transparent grid may compensate or eliminate disturbances in the second electrical field provided by the second electrode 120. For example, the electron transparent grid may compensate or eliminate disturbances in the second electrical field which may be caused by irregularities in the second electrode, e.g. openings in the second electrode. According to an embodiment, the at least one electron transparent portion includes an electron transparent grid.

The at least one electron transparent portion may include an electron transparent foil. The electron transparent foil may be configured for electrons to pass through the electron transparent foil. The electron transparent foil may be formed integrally with the second electrode 120 of the second electrode. The electron transparent foil may be highly transparent to electrons. The electron transparent foil may have an electron transparency of more than 50%, particularly more than 70%.

The electron transparent foil may be configured to apply a voltage to the electron transparent foil. The electron transparent foil may be electrically connected to the second electrode. The electron transparent foil may be configured to apply a same voltage which is applied to the second electrode to the electron transparent foil. Particularly, the electron transparent foil may be configured to apply the second voltage to the electron transparent foil. The electron transparent foil may compensate or eliminate disturbances in the second electrical field provided by the second electrode 120. For example, the electron transparent grid may compensate or eliminate disturbances in the second electrical field which may be caused by irregularities in the second electrode, e.g. openings in the second electrode. According to an embodiment, the at least one electron transparent portion includes an electron transparent foil.

According to an aspect, a signal electron beam deflector for an electron beam apparatus is provided. The signal electron beam deflector includes a first electrode and a second electrode providing a first optical path therebetween, and at least one electron transparent portion provided in the second electrode. A second optical path is provided, the second optical path passing through the at least one electron transparent portion, and the signal electron beam deflector is configured to guide electrons of a signal electron beam along the first optical path and along the second optical path according to an energy of the electrons of the signal electron beam. The at least one electron transparent portion may be configured to allow signal electrons to pass through the at least one electron transparent portion

In some embodiments, the at least on electron transparent portion includes an electron transparent grid or an electron transparent foil. In some embodiments, the signal electron beam deflector is configured to guide slow electrons of the signal electron beam having an energy of less than 500 eV upon emission or release from a sample along the first optical path and to guide fast electrons of the signal electron beam having an energy of more than 1 keV upon emission or release from the sample along the second optical path. In some embodiments, the at least one electron transparent portion 130 includes a beam opening in the second electrode. The beam opening may be a slit in the second electrode extending between a first end of the second electrode at the entrance opening and a second end of the second electrode at the exit opening.

The signal electron beam deflector 100 according to embodiments described herein allows to deflect a signal electron beam such that slow signal electrons are guided along a first optical path and fast signal electrons are guided along a second optical path. The at least one electron transparent portion 130 provides an exit for the fast signal electrons. Advantageously, fast signal electrons having an energy up to 20 keV, even up to 100 keV upon emission or release from the sample can be guided along the second optical path. Simultaneously, slow signal electrons having an energy of less than 1 keV, particularly less than 100 eV, upon release or emission from the sample can be guided along the first optical path.

### Cross-Sectional Shape

Referring now to FIGS. 3A-3C, the first electrode 110 and the second electrode 120 are shown in a cross-sectional view for different embodiments. The first electrical field provided by the first electrode may be dependent on the cross-sectional shape of the first electrode. Particularly, the first electrical field within the space 140 may be dependent on the first cross-sectional shape of the first electrode. The second electrical field provided by the second electrode may be dependent on the second cross-sectional shape of the second electrode. Particularly, the second electrical field within the space 140 may be dependent on the cross-sectional shape of the second electrode.

As shown in FIGS. 3A-3C, the first electrode 110 and/or the second electrode may extend along a direction into the paper plane and/or out of the paper plane having the first/second cross-sectional shape. The first electrode 110 and/or the second electrode may be curved in a direction into the paper plane and/or out of the paper plane as described herein.

FIG. 3A shows a cross sectional view of the first electrode and of the second electrode according to embodiments described herein. A first part of the first electrode is defined by a straight line. A second part of the second electrode is defined by a straight line. The first optical path 170 may be provided between the first part and the second part. The first electrode and the second electrode are arranged parallel to each other. FIG. 3A shows the at least one electron transparent portion 130 including a beam opening provided in the second electrode. The beam opening may be provided as a slit in the second electrode extending between the first end of the second electrode at the entrance opening and the second end of the second electrode at the exit opening.

In some embodiments, which can be combined with other embodiments described herein, the first electrode may have a first cross section in a plane perpendicular to the first optical path, and the second electrode may have a second cross section in the plane perpendicular to the first optical path; and a first part of the first cross section may be defined by a straight line, and a second part of the second cross section may be defined by a straight line.

FIG. 3B shows a cross sectional view of the first electrode 110 and of the second electrode 120 according to embodiments described herein. A first part of the first electrode is defined by a circular arc. A second part of the second electrode is defined by a circular arc. The first optical path 170 may be provided between the first part and the second part. A circular arc defining the first part and/or the second part may have any suitable shape. The circular arc may have any suitable opening angle and/or any suitable radius. In an embodiment, the first part defined by a circular arc and the second part defined by a circular arc are concentric. The first part defined by a circular arc and the second part defined by a circular arc may be curved in a same direction. FIG. 3B shows the second electrode 120 provided as an electron transparent grid. The at least one electron transparent portion 130 extends substantially over the entire surface of the second electrode that is provided as an electron transparent grid.

In some embodiments, which can be combined with other embodiments described herein, the first electrode may have a first cross section in a plane perpendicular to the first optical path, and the second electrode may have a second cross section in the plane perpendicular to the first optical path; and a first part of the first cross section may be defined by an elliptical arc, and a second part of the second cross section may be defined by an elliptical arc. An elliptical arc defining the first electrode and/or the second electrode may have any suitable shape. The elliptical arc may have any suitable opening angle and any suitable length of the semi-major axis and the semi-minor axis, particularly any suitable ratio of the semi-major axis to the semi-minor axis. In an embodiment, the semi-major axis and the semi-minor axis may have same length, forming a circular arc.

FIG. 3C shows a cross sectional view of the first electrode 110 and of the second electrode according to embodiments described herein. A first part of the first electrode may be defined by a polynomial. A second part of the second electrode may be defined by an exponential function. The first optical path 170 may be provided between the first part and the second part. The first part of the first electrode may be different to a second part of the second electrode. Advantageously, a hexapole component of an electrical field may be reduced or compensated thereby. The first optical path may be provided between the first part and the second part. FIG. 3C shows the second electrode 120 provided as an electron transparent foil. The at least one electron transparent portion 130 extends substantially over the entire surface of the second electrode that is provided as an electron transparent foil.

While FIGS. 3A-3C show the second cross-sectional shape in certain combinations with the at least one electron transparent portion, it is understood, that any suitable cross-sectional shape of the second electrode can be provided with any suitable at least one electron transparent portion. For example, the second electrode 120 shown in FIG. 3B may have the at least one electron transparent portion including a beam opening or the second electrode 120 shown in FIG. 3B may be provided as an electron transparent foil and the at least one electron transparent portion 130 may extend substantially over the entire surface of the second electrode 120 that is provided as an electron transparent foil.

According to an embodiment, which can be combined with other embodiments described herein, the first electrode may have a first cross section in a plane perpendicular to the first optical path, and the second electrode may have a second cross section in the plane perpendicular to the first optical path; and a first part of the first cross section and a second part of the second cross section may provide the first optical path therebetween, and wherein the first part of the first cross section may be defined by a polynomial and the second part of the second cross section may be defined by an exponential function. At least a portion of the first electrode may be defined by a rotation of the polynomial around a first axis and/or at least a portion of the second electrode may be defined by a rotation of the exponential around a second axis.

In some embodiments, the first electrode may have a first cross section in a plane perpendicular to the first optical path, and the second electrode may have a second cross section in the plane perpendicular to the first optical path; and a first part of the first cross section and a second part of the second cross section may provide the first optical path therebetween, and wherein the first part of the first cross section may be defined by an analytical function or coordinate data points and/or the second part of the second cross section may be defined by an analytical function or coordinate data points.

### Electron Beam Apparatus

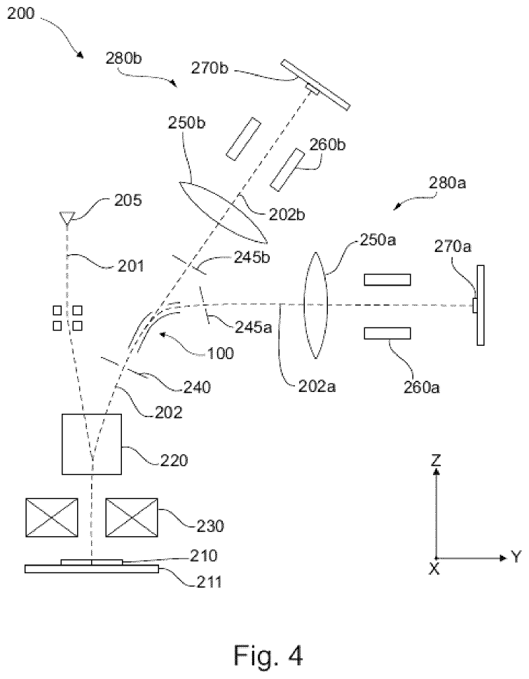

FIG. 4 shows a schematic view of an electron beam apparatus 200 according to the present disclosure. The electron beam apparatus having a signal electron beam deflector 100 according to the present disclosure. The electron beam apparatus includes an electron source 205 configured to generate a primary electron beam 201, a beam splitter 220 and an objective lens 230.

As shown in FIG. 4, the electron source 205 is configured to generate a primary electron beam 201. The primary electron beam 201 may be guided towards a sample 210. The primary electron beam 201 may be guided through a beam splitter 220 in a first propagation direction. The primary electron beam 201 may pass through the beam splitter and may be guided towards the sample 210 placed on a sample stage.

The primary electron beam 201 may pass through the objective lens 230. The objective lens 230 may focus the primary electron beam 201 on a surface of the sample 210. The primary electron beam 201 may impinge on the sample 210. The primary electron beam 201 may be accelerated between the electron source 205 and the sample 210. Particularly, the primary electron beam 201 may be accelerated between the objective lens 230 and the sample 210. The primary electron beam 201 may be accelerated such that the primary electron beam 201 has an energy of up to 20 keV, particularly up to 100 keV, when impinging on the sample.

Upon impingement of the primary electron beam 201 on the sample 210, a signal electron beam is emitted from the sample. The signal electron beam may include backscattered electrons (BSE) and/or secondary electrons (SE). The signal electron beam upon emission from the sample surface may have an energy of up to 20 keV, particularly up to 100 keV. The BSEs may have an energy between 1 keV to 100 keV upon emission from the sample surface. The SEs may have an energy of up to 50 eV upon emission from the sample surface. The signal electron beam may be guided through the objective lens 230. The signal electron beam may be guided through the beam splitter 220.

The beam splitter 220 may be configured to separate the primary electron beam 201 and the signal electron beam 202. In the space between the beam splitter 220 and the sample 210 the primary electron beam and the signal electron beam may propagate along a same path. The primary electron beam 201 may propagate along a first path from the electron source 205 to the beam splitter 220. The signal electron beam 202 may propagate along a second path from the beam splitter towards the signal electron beam deflector 100. The beam splitter may deflect the primary electron beam 201 and the signal electron beam 202, such that the first path and the second path are not overlapping.

For example, the beam splitter 220 may be a magnetic beam splitter and a deflection of an electron beam propagating through the beam splitter 220 may be dependent on a propagation direction of the electron beam. The primary electron beam 201 may propagate through the beam splitter 220 along a first propagation direction. The beam splitter 220 may deflect the primary electron beam 201, such that the primary electron beam propagates along a deflected first propagation direction. The primary electron beam 201 may propagate along the deflected first propagation direction between the beam splitter and the sample. The signal electron beam may propagate along a second propagation direction between the sample and the beam splitter. The second propagation direction may be substantially antiparallel to the deflected first propagation direction. The beam splitter 220 may deflect the signal electron beam 202, such that the signal electron beam 202 propagates along a deflected second propagation direction. The signal electron beam 202 may propagate along the deflected second propagation direction. The first propagation direction and the deflected second propagation direction may not be parallel and not be antiparallel. The signal electron beam 202 may exit the beam splitter 220 at a location different to a location where the primary electron beam 201 enters the beam splitter 220.

As shown in FIG. 4, the signal electron beam 202 may propagate from the beam splitter 220 towards the signal electron beam deflector 100. An acceleration energy may be provided to the signal electron beam 202. The acceleration energy may be provided to the signal electron beam during propagation of the signal electron beam from the sample or the beam splitter 220 towards the signal electron beam deflector. The acceleration energy may be provided by an acceleration voltage Vₐ. The acceleration voltage may be up to 10 kV, even up to 30 kV. The acceleration voltage may be between 10 kV and 30 kV. The acceleration energy may be up to 10 keV, even up to 30 keV. The acceleration energy may between 10 keV and 30 keV.

The signal electron beam deflector 100 may be according to embodiments described herein. The signal electron beam 202 may enter the signal electron beam deflector through the entrance opening. Slow electrons may be guided along the first optical path provided in the signal electron beam deflector. Slow electrons may exit the signal electron beam deflector 100 through the exit opening. Slow electrons exiting the signal electron beam deflector 100 through the exit opening may form a slow signal electron beam. Fast electrons may be guided along the second optical path provided in the signal electron beam deflector. Fast electrons may exit the signal electron beam deflector 100 through the at least one electron transparent portion. Fast electrons exiting the signal electron beam deflector 100 through the at least one electron transparent portion may form a fast signal electron beam.

The electron beam apparatus may include one or more apertures. An entrance aperture 240 may be positioned adjacent to the entrance opening of the signal electron beam deflector. A first aperture 245a may be positioned adjacent to the exit opening of the signal electron beam deflector. A second aperture 245b may be positioned adjacent to the at least one electron transparent portion of the signal electron beam deflector. A hexapole of an electric fringe field can be reduced by shaping at least one of the entrance aperture 240, the first aperture 245a and/or the second aperture 245b in a triangular fashion.

The electron beam apparatus may include a first detector arm 280a for detecting slow electrons of the signal electron beam. Particularly, for detecting the slow signal electron beam. The first detector arm 280a may include the first aperture 245a, a first focusing lens 250a for focusing the slow signal electron beam 202a, a first deflector 260a for adjusting a path of the slow signal electron beam 202a and/or a first detector 270a for detecting the slow signal electron beam. The first detector arm may include a first detector arm optical axis. The first aperture 245a, the first focusing lens 250a, the first deflector 260a and/or the first detector 270a may be aligned with the first detector arm optical axis. The first detector arm may be placed adjacent to the exit opening 160 of the signal electron beam deflector 100. Particularly, such that the first aperture 245a is positioned adjacent to the exit opening 160 of the signal electron beam deflector 100. The first detector arm may be aligned with the first optical path. Particularly, the first detector arm optical axis may be aligned with the first optical path. The first detector arm may be placed such that the first detector arm optical axis and a direction of the first optical path at the exit opening are parallel. Particularly, placed such that the first detector arm optical axis and the first optical path are merged.

The slow signal electron beam may exit the signal electron beam deflector 100 through the exit opening 160. The slow signal electron beam may propagate through the first aperture 245a. The slow signal electron beam may propagate through the first focusing lens 250a. The first focusing lens 250a may focus the slow signal electron beam to a location of the first detector 270a. The slow signal electron beam may propagate through the first deflector 260a. The first deflector 260a may adjust a position at which the slow signal electron beam impinges on the first detector 270a. The first detector 270a may detect the slow signal electron beam. The first detector 270 may image the sample 210.

The electron beam apparatus may include a second detector arm 280b for detecting fast electrons of the signal electron beam. Particularly, for detecting the fast signal electron beam. The second detector arm 280b may include the second aperture 245b, a second focusing lens 250b for focusing the fast signal electron beam 202b, a second deflector 260b for adjusting a path of the fast signal electron beam 202b and/or a second detector 270b for detecting the fast signal electron beam. The second detector arm may include a second detector arm optical axis. The second aperture 245b, the second focusing lens 250b, the second deflector 260b and/or the second detector 270b may be aligned with the second detector arm optical axis. The second detector arm optical axis may be placed adjacent to the at least one electron transparent portion of the signal electron beam deflector 100. Particularly, such that the second aperture 245b is positioned adjacent to the at least one electron transparent portion of the signal electron beam deflector 100. The second detector arm may be aligned with the second optical path. Particularly, the second detector arm axis may be aligned with the first optical path. The second detector arm may be placed such that the second detector arm optical axis and a direction of the second optical path at the exit opening are parallel. Particularly placed such that the second detector arm optical axis and the second optical path are merged.

The fast signal electron beam may exit the signal electron beam deflector 100 through the at least one electron transparent portion 130. The fast signal electron beam may propagate through the second aperture 245b. The slow signal electron beam may propagate through the second focusing lens 250b. The second focusing lens 250b may focus the fast signal electron beam to a location of the second detector 270b. The fast signal electron beam may propagate through the second deflector 260b. The second deflector 260b may adjust a position at which the fast signal electron beam impinges on the second detector 270b. The second detector 270b may detect the fast signal electron beam. The second detector 270b may image the sample 210.

According to an aspect an electron beam apparatus is provided. The electron beam apparatus includes a sample stage, a deflector system, an electron source adapted to generate a primary electron beam and a signal electron beam deflector according to embodiments described herein.

### Method of Deflecting a Signal Electron Beam

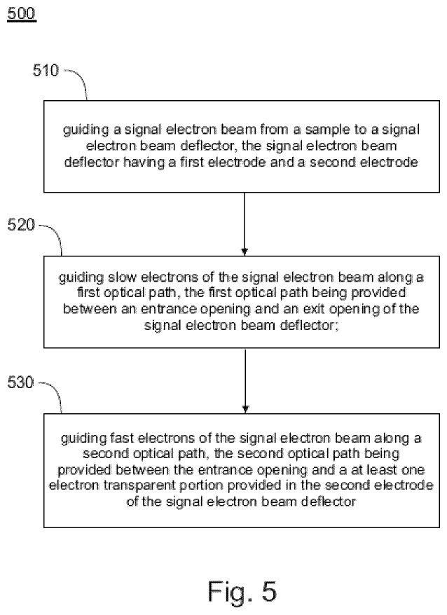

FIG. 5 shows a flow chart of a method of deflecting a signal electron beam according to embodiments described herein. At operation 510 a signal electron beam can be guided from a sample to a signal electron beam deflector. The signal electron beam deflector having a first electrode and a second electrode. The signal electron beam deflector may be a signal electron beam deflector according to embodiments described herein. The signal electron beam may be emitted from the sample upon impingement of a primary electron beam. The primary electron beam may have an energy of up to 20 keV, particularly up to 100 keV. The signal electron beam may include backscattered electrons and/or secondary electrons.

At operation 520 slow electrons of the signal electron beam having an energy less than 500 eV upon emission or release from the sample may be guided along a first optical path. Particularly, slow electrons may include secondary electrons and/or low energy backscattered electrons. The first optical path being provided between an entrance opening and an exit opening of the signal electron beam deflector. The guiding of the slow electrons of the signal electron beam may include deflecting the slow electrons by a first electrical field provided by the first electrode and/or a second electrical field provided by the second electrode. The slow electrons may be deflected by a first angle α. The first angle α is measured between a propagation direction of the slow electrons when entering the signal electron beam deflector, i.e. a propagation direction of the signal electron beam when entering the signal electron beam deflector, and a propagation direction of the slow electrons when exiting the signal electron beam deflector. The first angle α may be between 30° and 90°.

At operation 530 fast electrons of the signal electron beam having an energy of more than 1 keV upon emission or release from the sample may be guided along a second optical path. Particularly, fast electrons may include backscattered electrons. The second optical path being provided between the entrance opening and a at least one electron transparent portion provided in the second electrode of the signal electron beam deflector. The guiding of the fast electrons of the signal electron beam may include deflecting the fast electrons by the first electrical field and/or by the second electrical field. The fast electrons may be deflected by a second angle β. The second angle β is measured between a propagation direction of the fast electrons when entering the signal electron beam deflector, i.e. a propagation direction of the signal electron beam when entering the signal electron beam deflector, and a propagation direction of the fast electrons when exiting the signal electron beam deflector. The second angle β may be between substantially 10° and 80°. The second angle β may be less than the first angle α. In one embodiment, the first angle α is between 80° and 90° and the second angle β is between 30° and 80°.

According to an aspect, a method of deflecting a signal electron beam is provided. The method includes guiding a signal electron beam from a sample to a signal electron beam deflector, the signal electron beam deflector having a first electrode and a second electrode: guiding slow electrons of the signal electron beam along a first optical path, the first optical path being provided between an entrance opening and an exit opening of the signal electron beam deflector; and guiding fast electrons of the signal electron beam along a second optical path, the second optical path being provided between the entrance opening and a at least one electron transparent portion provided in the second electrode of the signal electron beam deflector. The signal electron beam deflector may be a signal electron beam deflector according to embodiments described herein.

The method may include an additional operation of detecting the slow electrons by a first detector and/or detecting the fast electrons by a second detector. The first detector may detect the slow electrons to image the sample. The second detector may detect the fast electrons to image the sample.

According to an embodiment, slow electrons have an energy of less than 1 keV upon emission or release from the sample and fast electrons have an energy of more than 1 keV and, e.g. less than 200 keV or less than 100 keV upon emission or release from the sample. Particularly, slow electrons may have an energy of less than 100 eV upon emission or release from the sample.

According to an embodiment, the first electrode and the second electrode are arranged adjacent to each other to form a space between the first electrode and the second electrode, such that the space has the entrance opening and the exit opening.

According to an embodiment, which can be combined with further embodiments described herein, the method may further include providing a first voltage to a first electrode of the signal electron beam deflector to generate a first electrical field: providing a second voltage to a second electrode of the signal electron beam deflector to generate a second electrical field: deflecting the slow electrons by the first electrical field and by the second electrical field; and deflecting the fast electrons by the first electrical field and by the second electrical field. The deflecting the slow electrons by the first electrical field and by the second electrical field may guide the slow electrons along the first optical path. The deflecting the fast electrons by the first electrical field and by the second electrical field may guide the fast electrons along the second optical path.

According to an embodiment, the method further includes applying the second voltage to an electron transparent grid provided as the at least one electron transparent portion. According to an embodiment, the method further includes applying the second voltage to an electron transparent foil provided as the at least one electron transparent portion.

According to an embodiment, which can be combined with further embodiments described herein, the guiding the slow electrons along the first optical path includes deflecting the slow electrons by a first angle α, the first angle α being between 30° and 90°, and the guiding the fast electrons along the second optical path includes deflecting the fast electrons by a second angle β, the second angle β being between 0° and 80°. Particularly, the first angle α being between 80° and 90° and the second angle β being between 30° and 80°.

According to an embodiment, the guiding the signal electron beam from the sample to the signal electron beam deflector includes accelerating the signal electron beam with an acceleration voltage Vₐ between the sample and the signal electron beam deflector, the acceleration voltage Vₐ being between 10 keV and 30 keV.

Embodiments of the present disclosure may include the following clauses.

Clause 1. A signal electron beam deflector for an electron beam apparatus, the signal electron beam deflector including: a first electrode extending in a curved manner; and a second electrode extending in a curved manner and having at least one electron transparent portion: the first electrode and the second electrode are arranged adjacent to each other to form a space between the first electrode and the second electrode, such that: the space has an entrance opening and an exit opening: a first optical path is provided between the entrance opening and the exit opening; and a second optical path is provided between the entrance opening and the at least one electron transparent portion of the second electrode.

Clause 2. The signal electron beam deflector of clause 1, wherein the at least one electron transparent portion includes an electron transparent grid

Clause 3. The signal electron beam deflector of clauses 1, wherein the at least one electron transparent portion includes an electron transparent foil.

Clause 4. The signal electron beam deflector of any one of clauses 1 through 3, wherein the at least one electron transparent portion includes a beam opening in the second electrode, particularly wherein the beam opening is a slit in the second electrode extending between a first end of the second electrode at the entrance opening and a second end of the second electrode at the exit opening.

Clause 5. The signal electron beam deflector of any one of clauses 1 through 4, wherein: the second electrode is provided as an electron transparent grid or an electron transparent foil such that the at least one electron transparent portion extends substantially over the entire surface of the second electrode that is provided as an electron transparent grid or an electron transparent foil.

Clause 6. The signal electron beam deflector of any one of clauses 1 through 5, wherein: the first electrode has a first cross section in a plane perpendicular to the first optical path, and the second electrode has a second cross section in the plane perpendicular to the first optical path; and a first part of the first cross section is defined by an elliptical arc, and a second part of the second cross section is defined by an elliptical arc.

Clause 7. The signal electron beam deflector of any one of clauses 1 through 6, wherein the first electrode is extending in an elliptical manner and the second electrode is extending in an elliptical manner.

Clause 8. The signal electron beam deflector of any one of clauses 1 through 5 and 7, wherein: the first electrode has a first cross section in a plane perpendicular to the first optical path, and the second electrode has a second cross section in the plane perpendicular to the first optical path); and a first part of the first cross section and a second part of the second cross section provide the first optical path therebetween, and wherein the first part of the first cross section is defined by a polynomial and the second part of the second cross section is defined by an exponential function.

Clause 9. The signal electron beam deflector of any one of clauses 1 through 8, wherein the at least one electron transparent portion is configured for signal electrons to pass through the at least one electron transparent portion.

Clause 10. The signal electron beam deflector of any one of clauses 1 through 8, wherein the at least one electron transparent portion is configured for a portion of the signal electron beam to pass through the at least one electron transparent portion

Clause 11. A signal electron beam deflector for an electron beam apparatus, the signal electron beam deflector including: a first electrode and a second electrode providing a first optical path therebetween; and at least one electron transparent portion provided in the second electrode: wherein: a second optical path is provided, the second optical path passing through the at least one electron transparent portion; and the signal electron beam deflector is configured to guide electrons of a signal electron beam along the first optical path and along the second optical path dependent on an energy of the electrons of the signal electron beam.

Clause 12. The signal electron beam deflector of clause 11, wherein the at least one electron transparent portion includes an electron transparent grid or an electron transparent foil.

Clause 13. The signal electron beam deflector of any one of clauses 11 and 12, wherein the signal electron beam deflector is configured to guide slow electrons of the signal electron beam having an energy of less than 500 eV upon emission or release from the sample along the first optical path and to guide fast electrons of the signal electron beam having an energy of more than 1 keV upon emission or release from the sample along the second optical path.

Clause 14. The signal electron beam deflector of any one of clauses 11 through 13, wherein the at least one electron transparent portion is configured to allow signal electrons to pass through the at least one electron transparent portion

Clause 15. The signal electron beam deflector of any one of clauses 11 through 13, wherein the at least one electron transparent portion is configured to allow a portion of a signal electron beam to pass through the at least one electron transparent portion

Clause 16. An electron beam apparatus, including: a sample stage: a deflector system: an electron source adapted to generate a primary electron beam; and a signal electron beam deflector of clauses 1 through 15.

Clause 17. A method of deflecting a signal electron beam, the method including: guiding a signal electron beam from a sample to a signal electron beam deflector, the signal electron beam deflector having a first electrode and a second electrode: guiding slow electrons of the signal electron beam along a first optical path, the first optical path being provided between an entrance opening and an exit opening of the signal electron beam deflector; and guiding fast electrons of the signal electron beam along a second optical path, the second optical path being provided between the entrance opening and a at least one electron transparent portion provided in the second electrode of the signal electron beam deflector.

Clause 18. The method of clause 17, wherein slow electrons have an energy of less than 1 keV or less than 100 eV, upon emission or release from the sample, and fast electrons have an energy of more than 1 keV upon emission or release from the sample.

Clause 19. The method of any one of clauses 17 through 18, wherein the guiding the signal electron beam from the sample to the signal electron beam deflector includes accelerating the signal electron beam with the acceleration voltage Vₐ between the sample and the signal electron beam deflector, the acceleration voltage Vₐ being between 10 kV and 30 kV.

Clause 20. The method of any one of clauses 17 through 19, wherein the first electrode and the second electrode are arranged adjacent to each other to form a space between the first electrode and the second electrode, such that the space has the entrance opening and the exit opening.

Clause 21. The method of any one of clauses 17 through 20, further includes: providing a first voltage to the first electrode of the signal electron beam deflector to generate a first electrical field: providing a second voltage to the second electrode of the signal electron beam deflector to generate a second electrical field: deflecting the slow electrons by the first electrical field and by the second electrical field; and deflecting the fast electrons by the first electrical field and by the second electrical field.

Clause 22. The method of clause 21, further including: applying the second voltage to an electron transparent grid provided as the at least one electron transparent portion, the electron transparent grid.

Clause 23. The method of clause 21, further including: applying the second voltage to an electron transparent foil provided as the at least one electron transparent portion.

Clause 24. The method of any one of clauses 17 through 23, wherein the guiding the slow electrons along the first optical path includes deflecting the slow electrons by a first angle α, the first angle α being between 30° and 90°, and the guiding the fast electrons along the second optical path includes deflecting the fast electrons by a second angle β, the second angle β being between substantially 10° and 80°, particularly the first angle α being between 80° and 90° and the second angle β being between 30° and 80°.

Clause 25. The method of any one of clauses 17 through 24, wherein the signal electron beam deflector is a signal electron beam deflector according to any one of clauses 1 through 15.

While the foregoing is directed to embodiments of the disclosure, other and further embodiments of the disclosure may be devised without departing from the basic scope thereof, and the scope thereof is determined by the claims that follow.

1. A signal electron beam deflector for an electron beam apparatus, the signal electron beam deflector comprising:
a first electrode extending in a curved manner; and
a second electrode extending in a curved manner and having at least one electron transparent portion;
the first electrode and the second electrode are arranged adjacent to each other to form a space between the first electrode and the second electrode, such that:
the space has an entrance opening and an exit opening;
a first optical path is provided between the entrance opening and the exit opening; and
a second optical path is provided between the entrance opening and the at least one electron transparent portion of the second electrode.

2. The signal electron beam deflector of claim 1, wherein the at least one electron transparent portion comprises an electron transparent grid.

3. The signal electron beam deflector of claim 1, wherein the at least one electron transparent portion comprises an electron transparent foil.

4. The signal electron beam deflector of claim 1, wherein the at least one electron transparent portion comprises a beam opening in the second electrode, particularly wherein the beam opening is a slit in the second electrode extending between a first end of the second electrode at the entrance opening and a second end of the second electrode at the exit opening.

5. The signal electron beam deflector of claim 1, wherein:
the second electrode is provided as an electron transparent grid or an electron transparent foil such that the at least one electron transparent portion extends substantially over the entire surface of the second electrode that is provided as an electron transparent grid or an electron transparent foil.

6. The signal electron beam deflector of claim 1, wherein:
the first electrode has a first cross section in a plane perpendicular to the first optical path, and the second electrode has a second cross section in the plane perpendicular to the first optical path; and
a first part of the first cross section is defined by an elliptical arc, and a second part of the second cross section is defined by an elliptical arc.

7. The signal electron beam deflector of claim 1, wherein the first electrode is extending in an elliptical manner and the second electrode is extending in an elliptical manner.

8. The signal electron beam deflector of claim 1, wherein:
the first electrode has a first cross section in a plane perpendicular to the first optical path, and the second electrode has a second cross section in the plane perpendicular to the first optical path; and
a first part of the first cross section and a second part of the second cross section provide the first optical path therebetween, and wherein the first part of the first cross section is defined by a polynomial and the second part of the second cross section is defined by an exponential function.

9. A signal electron beam deflector for an electron beam apparatus, the signal electron beam deflector comprising:
a first electrode and a second electrode providing a first optical path therebetween; and
at least one electron transparent portion provided in the second electrode;
wherein:
a second optical path is provided, the second optical path passing through the at least one electron transparent portion; and
the signal electron beam deflector is configured to guide electrons of a signal electron beam along the first optical path and along the second optical path dependent on an energy of the electrons of the signal electron beam.

10. The signal electron beam deflector of claim 9, wherein the at least one electron transparent portion comprises an electron transparent grid or an electron transparent foil.

11. The signal electron beam deflector of claim 9, wherein the signal electron beam deflector is configured to guide slow electrons of the signal electron beam having an energy of less than 500 eV upon emission or release from a sample along the first optical path and to guide fast electrons of the signal electron beam having an energy of more than 1 keV upon emission or release from the sample along the second optical path.

12. An electron beam apparatus, comprising:
a sample stage;
a deflector system;
an electron source adapted to generate a primary electron beam; and
a signal electron beam deflector of claim 1.

13. A method of deflecting a signal electron beam, the method comprising:
guiding a signal electron beam from a sample to a signal electron beam deflector, the signal electron beam deflector having a first electrode and a second electrode;
guiding slow electrons of the signal electron beam along a first optical path, the first optical path being provided between an entrance opening and an exit opening of the signal electron beam deflector; and
guiding fast electrons of the signal electron beam along a second optical path, the second optical path being provided between the entrance opening and a at least one electron transparent portion provided in the second electrode of the signal electron beam deflector.

14. The method of claim 13, wherein slow electrons have an energy of less than 1 keV or less than 100 eV, upon emission or release from the sample, and fast electrons have an energy of more than 1 keV upon emission or release from the sample.

15. The method of claim 14, wherein the guiding the signal electron beam from the sample to the signal electron beam deflector comprises accelerating the signal electron beam with the acceleration voltage Vₐ between the sample and the signal electron beam deflector, the acceleration voltage Vₐ being between 10 kV and 30 kV.

16. The method of claim 13, wherein the first electrode and the second electrode are arranged adjacent to each other to form a space between the first electrode and the second electrode, such that the space has the entrance opening and the exit opening.

17. The method of claim 16, further comprising:
providing a first voltage to the first electrode of the signal electron beam deflector to generate a first electrical field;
providing a second voltage to the second electrode of the signal electron beam deflector to generate a second electrical field;
deflecting the slow electrons by the first electrical field and by the second electrical field; and
deflecting the fast electrons by the first electrical field and by the second electrical field.

18. The method of claim 17, further comprising:
applying the second voltage to an electron transparent grid or an electron transparent foil provided as the at least one electron transparent portion.

19. The method of claim 17, wherein the guiding the slow electrons along the first optical path comprises deflecting the slow electrons by a first angle α, the first angle α being between 30° and 90°, and the guiding the fast electrons along the second optical path comprises deflecting the fast electrons by a second angle β, the second angle β being between substantially 10° and 80°, particularly the first angle α being between 80° and 90° and the second angle β being between 30° and 80°.

20. The method of claim 13, wherein the signal electron beam deflector comprises:
a first electrode extending in a curved manner; and
a second electrode extending in a curved manner and having at least one electron transparent portion;
the first electrode and the second electrode are arranged adjacent to each other to form a space between the first electrode and the second electrode, such that:
the space has an entrance opening and an exit opening;
a first optical path is provided between the entrance opening and the exit opening; and
a second optical path is provided between the entrance opening and the at least one electron transparent portion of the second electrode.
